(19) United States
(12) Patent Application Publication
(10) Pub. No.: US 2026/0227435 A1
(43) Pub. Date: Aug. 6, 2026

(54) FAULT DETERMINATION SYSTEM, FAULT DETERMINATION METHOD, AND TRAINED MODEL GENERATION METHOD

(71) Applicant: NEC Corporation, Tokyo (JP)

(72) Inventors: Taiga HAGINOUCHI, Tokyo (JP); Toshiharu OOUCHI, Kanagawa (JP)

(73) Assignee: NEC Corporation, Tokyo (JP)

(21) Appl. No.: 19/448,423

(22) Filed: Jan. 14, 2026

(30) Foreign Application Priority Data
Feb. 4, 2025 (JP) 2025-017119

(51) Int. Cl. G01R 31/08; G06F 11/34

(52) U.S. Cl. CPC G01R 31/083; G01R 31/088; G06F 11/3476

(57) ABSTRACT

A fault determination system according to the present disclosure includes at least one memory storing instructions and at least one processor configured to execute the instructions to acquire an alarm log output from a plurality of configuration devices in a submarine cable system in which a fault has occurred, the alarm log including an occurrence time of the fault, input the alarm log acquired to a trained model that outputs a fault factor in the submarine cable system as a whole in a case where the alarm log is input, and output the fault factor from the trained model.

### INCORPORATION BY REFERENCE

This application is based upon and claims the benefit of priority from Japanese patent application No. 2025-017119, filed on February 4, 2025, the disclosure of which is incorporated herein in its entirety by reference.

### TECHNICAL FIELD

The present disclosure relates to a fault determination system, a fault determination method, and a trained model generation method.

### BACKGROUND ART

Various techniques have been proposed for specifying fault factors related to submarine cable systems using machine learning. For example, WO 2021/192316 A1 discloses a technique in which a failure cause estimation device included in a landing station in a submarine cable system estimates a failure cause (fault factor). The failure cause estimation device estimates the failure cause based on parameters related to information such as internal voltage and current of each transponder and quality of an optical signal to be transmitted and received. The estimation is performed by matching textbook data indicating a correlation between the distribution pattern of the parameters and the failure probabilities. The textbook data can be generated by machine learning based on an operation record of the submarine cable system.

### SUMMARY

In WO 2021/192316 A1, a failure cause estimation device estimates a fault factor for each station building based on parameters collected from transponders provided in each station building. That is, the failure cause estimation device does not comprehensively estimate the fault factor based on the parameters related to the entire submarine cable system. The submarine cable system is a large-scale network system including a plurality of station buildings, optical repeaters, and branching devices. Therefore, the factors of the fault are diverse, and are often complicated. In the determination for each station building like the failure cause estimation device of WO 2021/192316 A1, there is a possibility that the fault factor cannot be appropriately determined.

The present disclosure has been made to solve such a problem, and an example object thereof is to provide a fault determination system, a fault determination method, and a trained model generation method capable of appropriately determining a fault factor in the entire submarine cable system.

A fault determination system according to an example aspect of the present disclosure includes at least one memory storing instructions, and at least one processor configured to execute the instructions to acquire an alarm log output from a plurality of configuration devices in a submarine cable system in which a fault has occurred, the alarm log including an occurrence time of the fault, input the alarm log acquired to a trained model that outputs a fault factor in the submarine cable system as a whole in a case where the alarm log is input, and output the fault factor relevant to the alarm log input from the trained model.

A fault determination method according to an example aspect of the present disclosure includes, by a computer, acquiring an alarm log output from a plurality of configuration devices in a submarine cable system in which a fault has occurred, the alarm log including an occurrence time of the fault, inputting the alarm log acquired to a trained model that outputs a fault factor in the submarine cable system as a whole in a case where the alarm log is input, and outputting the fault factor relevant to the alarm log input from the trained model.

A trained model generation method according to an example aspect of the present disclosure includes, by a computer, acquiring teacher data output from a plurality of configuration devices in a submarine cable system in which a fault has occurred, the teacher data including an alarm log including an occurrence time of the fault and a fault factor in the submarine cable system as a whole; and generating a trained model that outputs the fault factor in a case where the alarm log is input, based on the teacher data.

An example advantage according to the present disclosure is to provide a fault determination system, a fault determination method, and a trained model generation method capable of appropriately determining a fault factor in the entire submarine cable system.

### BRIEF DESCRIPTION OF DRAWINGS

The above and other aspects, features, and advantages of the present disclosure will become more apparent from the following description of certain example embodiments in a case where taken in conjunction with the accompanying drawings, in which:

FIG. 1 is a block diagram illustrating a configuration of a fault determination system according to the present disclosure;

FIG. 2 is a flowchart illustrating an example of a flow of a fault determination method by a fault determination system;

FIG. 3 is a block diagram illustrating a configuration of a fault determination system according to the present disclosure;

FIG. 4 is a schematic diagram illustrating an example of contents displayed by a display unit;

FIG. 5 is a block diagram illustrating a configuration of a monitoring control system;

FIG. 6 is a flowchart illustrating an example of a flow of a fault determination method by a fault determination system;

FIG. 7 is a flowchart illustrating an example of a flow of a fault determination method in a monitoring control system; and

FIG. 8 is a diagram illustrating a hardware configuration example of a fault determination system.

### EXAMPLE EMBODIMENT

### First Example Embodiment

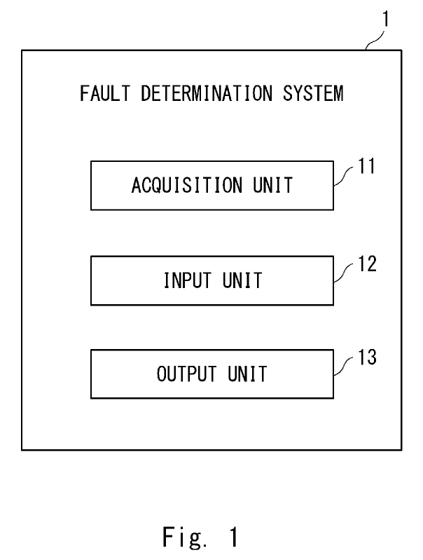

A first example embodiment according to the present disclosure will be described below with reference to the drawings. FIG. 1 is a block diagram illustrating a configuration of a fault determination system 1 according to the present disclosure. The fault determination system 1 is a system that determines a factor of a fault occurring in a submarine cable system. The fault determination system 1 may include a single device or a plurality of devices. The submarine cable system targeted by the fault determination system 1 includes a submarine cable, a station building, an optical repeater, and a branching device. The submarine cable system may be referred to as an optical submarine cable system. The submarine cable may also be referred to simply as a cable.

The submarine cable is an optical transmission path including one or more optical fibers. The submarine cable may be referred to as an optical submarine cable. The station building is installed on land and has a function of converting a data signal received from a land network into an optical signal and converting an optical signal received from a submarine cable into a data signal. In other words, the station building includes an optical transmission terminal station device. The optical transmission terminal station device includes a transponder. The station building has a function of transmitting an optical signal converted by the optical transmission terminal station device to the submarine cable or receiving an optical signal from the submarine cable. In other words, the station building includes an optical transmission device. Further, the station building has a power feeding function of supplying power of a constant current to the optical repeater. In other words, the station building includes a power feeding device. Further, the station building has a transmission path monitoring function. The transmission path monitoring function is a function of monitoring a submarine transmission path apparatus such as a submarine cable, an optical repeater, or a branching device. In other words, the station building includes a transmission path monitoring device. The station building may be referred to as any of a landing station, a land station, and a terminal station.

The optical repeater has an amplification function of amplifying an optical signal attenuated in the submarine cable. The optical repeater operates with a constant current supplied from the station building. The branching device has a function of branching the submarine cable into a plurality of cables. Specifically, the branching device has a function of switching a path of an optical signal and a power feeding path.

In a case where a fault occurs in the submarine cable system, a device related to the fault among the optical transmission terminal station device, the optical transmission device, the power feeding device, and the transmission path monitoring device included in the station building can output an alarm caused by the fault. Similarly, the optical repeater and the branching device may be able to output an alarm in a case where a fault occurs. Among the components of the submarine cable system, the element capable of generating an alarm is referred to as a configuration device of the submarine cable.

The fault determination system 1 includes an acquisition unit 11, an input unit 12, and an output unit 13. The acquisition unit 11 and the input unit 12 are data-communicably connected. Similarly, the input unit 12 and the output unit 13 are data-communicably connected to the trained model. Here, each data communication may be performed by wired connection or wireless connection. Data communication may be performed in the same device, may be performed via an Internet line, or may be performed by using a near field communication technology. A type of a communication protocol in data communication is not limited.

The acquisition unit 11 acquires an alarm log output from a plurality of configuration devices in the submarine cable system in which a fault has occurred and including an occurrence time of the fault. Here, the alarm log is data in which an occurrence time and an alarm content related to an alarm output by the configuration device are recorded in association with each other. The acquisition unit 11 may acquire the alarm log from the configuration device, or may acquire the alarm log from another device and a terminal. The acquisition unit 11 transmits the acquired alarm log to the input unit 12.

In a case where the alarm log is input, the input unit 12 inputs the acquired alarm log to a trained model that outputs a fault factor in the entire submarine cable system. The machine learning algorithm in the trained model is, for example, a decision tree. Specifically, the machine learning algorithm may use gradient boosting or random forest. The machine learning algorithm may be a neural network (NN) such as a convolutional neural network (CNN), a support vector machine (SVM), and logistic regression. The “entire submarine cable system” may refer to an entire system including all components connected via a submarine cable, or may refer to a system including some components. In other words, the “entire submarine cable system” may refer to a system in which some of the connected components are removed. For example, in the case of a submarine cable system in which two regions in which the submarine cables are densely packed are connected by one submarine cable, “the entire submarine cable system” may refer to one of the two dense regions.

In a case where the alarm log is input, the output unit 13 outputs a fault factor relevant to the input alarm log from the trained model. That is, the trained model outputs the fault factor in the entire submarine cable system in a case where the alarm log is input. The fault factors are, for example, cable disconnection, optical fiber disconnection, cable open, repeater failure, and terminal station device fault. The number of fault factors may be one or plural. The output unit 13 may output the fault factor in a form that can be confirmed by the user, or may output the fault factor in a form that can be input to another device or terminal.

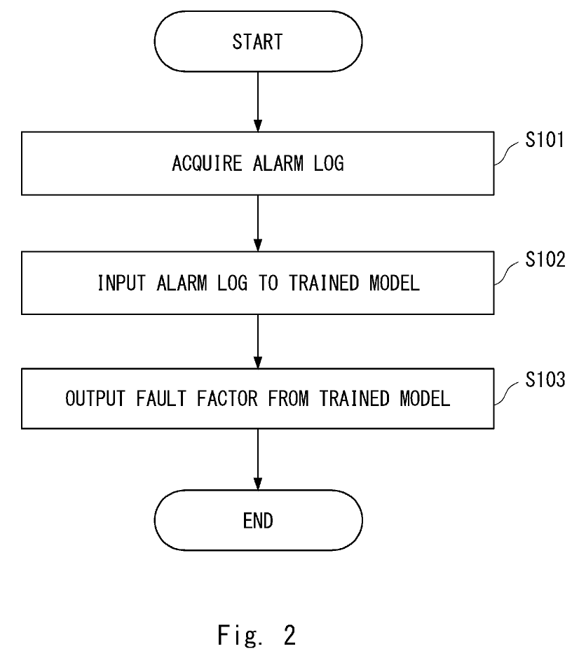

Next, a flow of a fault determination method by the fault determination system 1 will be described. FIG. 2 is a flowchart illustrating an example of a flow of a fault determination method by the fault determination system 1. First, the acquisition unit 11 acquires alarm logs output from a plurality of configuration devices in the submarine cable system (S101). Next, the input unit 12 inputs the alarm log acquired by the acquisition unit 11 to the trained model (S102). Finally, the output unit 13 outputs the fault factor in the entire submarine cable system from the trained model to which the alarm log has been input by the input unit 12 (S103).

As described above, in the present example embodiment, the alarm log is acquired from a plurality of configuration devices in the submarine cable system. Then, by inputting the alarm log to the trained model, the fault factor in the entire submarine cable system is output. In a case where a fault occurs in a submarine cable system including a plurality of configuration devices, the fault factors are diverse, and are often complicated. Therefore, in a case where an attempt is made to determine a fault factor for each station building based on data collected from some configuration devices in the station building, there is a possibility that the fault factor cannot be appropriately determined. In the present example embodiment, it is possible to output the fault factor of the entire submarine cable system by inputting the alarm log collected from the plurality of configuration devices including the optical transmission terminal station device including the transponder to the trained model. As a result, in the present example embodiment, it is possible to appropriately determine the fault factor in the entire submarine cable system.

### Second Example Embodiment

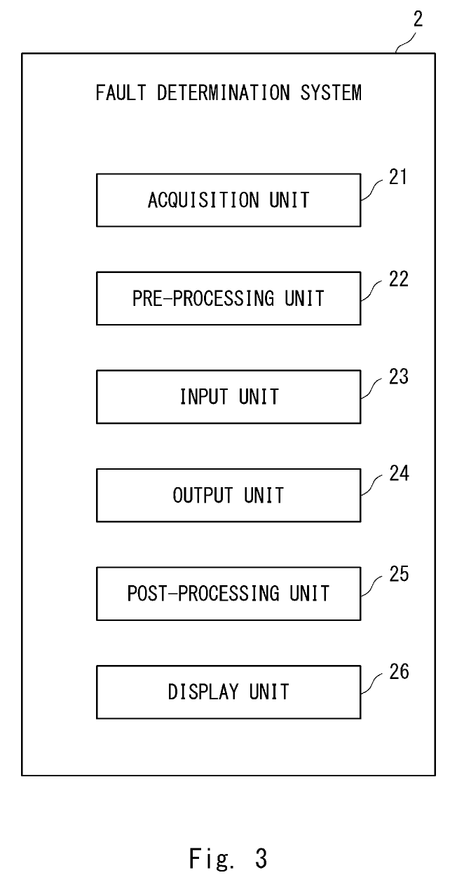

The present second example embodiment is a specific example of the first example embodiment described above. FIG. 3 is a block diagram illustrating a configuration of a fault determination system 2 according to the present disclosure. The fault determination system 2 includes an acquisition unit 21, a pre-processing unit 22, an input unit 23, an output unit 24, a post-processing unit 25, and a display unit 26. In the fault determination system 2, the acquisition unit 21, the input unit 23, and the output unit 24 are relevant to the acquisition unit 11, the input unit 12, and the output unit 13 in the fault determination system 1. Hereinafter, for clarity of description, description overlapping with the first example embodiment will be appropriately omitted.

In the fault determination system 2, the acquisition unit 21 and the pre-processing unit 22, the acquisition unit 21 and the post-processing unit 25, the pre-processing unit 22 and the input unit 23, the output unit 24 and the post-processing unit 25, and the post-processing unit 25 and the display unit 26 are connected so as to be able to perform data communication. These data communications may be performed by wired connection or wireless connection.

The data communication may be performed in the same device, may be performed via an Internet line, or may be performed using a near field communication technology. A type of a communication protocol in data communication is not limited.

In a case where a fault occurs in the submarine cable system, a device related to the fault among the configuration devices of the submarine cable system can output an alarm due to the fault. Here, the configuration device of the submarine cable system can output that no alarm has occurred in a case where no fault has occurred in the system, that is, even in a normal state. In other words, the configuration device can output that the device is normal.

The configuration device outputs an alarm log in a format in which an alarm occurrence time, an alarm name, and an alarm occurrence situation are associated with each other. Here, the alarm occurrence situation is, for example, the presence or absence of an alarm occurrence. That is, the alarm occurrence situation in this case is data indicating whether no alarm has occurred or whether an alarm has occurred. In a case where the alarm contents are categorical data different in stages, the alarm occurrence situation is data indicating whether no alarm has occurred and at which stage an alarm has occurred. The configuration device can output the alarm log in a table format or a matrix format, for example. The configuration device may output the name of the alarm and the alarm occurrence situation as a character string or a numerical value.

The configuration device of the submarine cable system can output a performance monitoring (PM) log. The PM log is time-series data on a monitored value (measured value) constantly monitored by the monitoring control system in the submarine cable system. Here, the monitored value includes a value related to power feeding and a value related to an optical signal. The value related to power feeding is, for example, a power value, a voltage value, and a current value of DC power supplied to the optical repeater. The power value, the voltage value, and the current value of the power may be values related to power transmitted from the power feeding device, or may be values related to power received by the optical repeater. The value related to the optical signal is, for example, a value related to the optical signal quality. Specifically, the value related to the optical signal quality is a quality factor (Q factor), a bit error rate (BER), or a signal-to-noise ratio (SNR). The value related to the optical signal is measured by, for example, an optical signal terminal station device.

The configuration device outputs the PM log in a format in which the measurement time, the name of the measurement target data, and the monitored value are associated with each other. The configuration device may output the PM log in a table format or a matrix format. The configuration device may output the name of the measurement target data as a character string or as a numerical value. The alarm log and the PM log may be collectively referred to as an alarm/PM log.

The acquisition unit 21 acquires alarm logs output from a plurality of configuration devices in the submarine cable system. Here, the acquisition unit 21 can further acquire the PM log from the configuration device. That is, the acquisition unit 21 can acquire the alarm/PM log from the configuration device. The alarm/PM log acquired by the acquisition unit 21 includes a log at a fault occurrence time. The acquisition unit 21 may directly acquire the alarm/PM log from the configuration device, or may acquire the alarm/PM log from another device or terminal. The acquisition unit 21 transmits the acquired alarm/PM log to the pre-processing unit 22 and the post-processing unit 25. Here, in a case of acquiring only the alarm log, the acquisition unit 21 transmits only the alarm log to the pre-processing unit 22 and the post-processing unit 25.

The pre-processing unit 22 performs pre-processing on the alarm/PM log input to the trained model by the input unit 23. First, the pre-processing unit 22 receives the alarm/PM log from the acquisition unit 11. Then, the pre-processing unit 22 generates a pre-processing log based on the received data. For example, regarding the alarm log, in a case where the name of the alarm or the alarm occurrence situation among the alarm contents in the alarm log acquired by the acquisition unit 21 is a character string, the pre-processing unit 22 performs processing of converting the character string into a numerical value. That is, in a case where the alarm content related to the alarm log includes a character string, the pre-processing unit 22 generates the pre-processing log by converting the character string into a numerical value. Here, in a case where the name of the alarm is a character string, the pre-processing unit 22 converts the character string into a relevant numerical value based on, for example, a predetermined correspondence relationship between the name of the alarm and the numerical value.

In a case where the alarm occurrence situation is a character string and the alarm occurrence situation represents the presence or absence of an alarm occurrence, the pre-processing unit 22 converts “no alarm” into “0” and converts “alarm” into “1”, for example. That is, in this case, the pre-processing unit 22 binarizes the alarm occurrence situation. In a case where the alarm occurrence situation is indicated in stages, the pre-processing unit 22 can convert such categorical data into a numerical value by performing dummy variable conversion (one-hot encoding).

In a case where the name of the measurement target data is a character string for the PM log, the pre-processing unit 22 performs processing of similarly converting the character string into a numerical value. That is, the pre-processing unit 22 converts the character string into a relevant numerical value based on, for example, a predetermined correspondence relationship between the name of the measurement target data and the numerical value.

The pre-processing unit 22 performs processing of expressing an abnormal change in the variation amount of the monitored value with a numerical value for the PM log. Specifically, the pre-processing unit 22 generates a pre-processing log by performing processing of classifying whether the variation amount of the monitored value is abnormal or the degree of abnormality of the variation amount in stages by a threshold value. That is, the pre-processing unit 22 generates a pre-processing log by binarizing an abnormal change in the variation amount of the monitored value or converting the abnormal change into a dummy variable. The variation amount of the monitored value refers to a variation range of the monitored value in a predetermined time section. The variation range of the monitored value may refer to a difference from a minimum value to a maximum value in the time section, or may refer to a deviation amount in an increasing direction or a decreasing direction with respect to a certain reference value. The time section may be a unit time or a plurality of times.

The pre-processing log generated by the pre-processing unit 22 may be in a table format or a matrix format. That is, similarly to the alarm/PM log received from the acquisition unit 21, the pre-processing unit 22 generates a pre-processing log in a format in which data in the log is associated with each other. The pre-processing unit 22 may generate a pre-processing log in a format similar to that of the alarm/PM log received from the acquisition unit 21.

The pre-processing unit 22 transmits the generated pre-processing log to the input unit 23. Here, in a case of receiving only the alarm log from the acquisition unit 21, the pre-processing unit 22 performs pre-processing only for the alarm log. In this case, the pre-processing unit 22 transmits the pre-processing log generated for the alarm log to the input unit 23.

The input unit 23 receives the pre-processing log from the pre-processing unit 22. Then, the input unit 23 inputs the pre-processing log to the trained model as an alarm/PM log. Here, in a case where only the pre-processing log for the alarm log is received from the pre-processing unit 22, the input unit 23 inputs the pre-processing log as the alarm log to the trained model.

A trained model and a method for generating the trained model in the present example embodiment will be described. Similarly to the first example embodiment, the machine learning algorithm in the trained model is, for example, a decision tree, an NN, an SVM, and logistic regression. In the case of decision tree based, the machine learning algorithm may use gradient boosting, random forest, or other algorithms. In a case where the decision tree-based machine learning algorithm is used, the trained model has a decision tree structure in which a branch condition is learned by using teacher data in which alarm/PM logs output from a plurality of configuration devices are input and a fault factor in the entire submarine cable system is output. Such a trained model is configured to input an alarm/PM log into the decision tree structure and output a fault factor by branching.

In a case where an NN-based machine learning algorithm is used, the trained model includes an input layer to which alarm/PM logs output from a plurality of configuration devices are input, and an output layer that outputs a fault factor in the entire submarine cable system. The trained model includes an intermediate layer in which a parameter is learned using teacher data to which an alarm/PM log is input and a fault factor is output. Such a machine learning model is configured to input an alarm/PM log to an input layer, perform calculation in an intermediate layer, and output a fault factor from an output layer.

That is, the trained model uses data including alarm/PM logs output from a plurality of configuration devices in the submarine cable system and a fault factor in the entire submarine cable system as teacher data. Then, it is possible to generate a trained model that outputs a fault factor in a case where the alarm/PM log is input, based on the teacher data. Here, even in a case where any machine learning model is used, the trained model can be generated without using the PM log. That is, it is possible to use teacher data to which only alarm logs output from a plurality of configuration devices are input. Then, the trained model trained using such teacher data is configured to output the fault factor using only the alarm log as an input.

The trained model may be generated using the above generation method so as to further output the occurrence position information of the fault in a case where the pre-processing log is input. Here, the occurrence position information is information regarding a position where it is estimated that a fault has occurred. The occurrence position information is, for example, information regarding the station building where the alarm has occurred, a section of the optical repeater where the fault has occurred, a number of the optical repeater where the fault has occurred, and information regarding a breaking point where the cable is broken. Here, the information regarding the breaking point can also be simply referred to as breaking point information. The breaking point information is typically a distance from the reference point to a place where the cable is broken. In this case, the trained model further inputs cable configuration information including a cable length and a cable resistance value, which is configuration information for each submarine cable system. As a result, the trained model outputs the cable configuration information and the breaking point information calculated based on, for example, the voltage value and the current value at the time of fault among the PM log related to power feeding in the pre-processing log.

In a case where the occurrence position information of the fault is output, the trained model may output the occurrence position information of the fault by extracting predetermined data from the pre-processing log based on the estimated fault factor. Specifically, the trained model may output the occurrence position information by extracting data regarding the fault factor in the fault occurrence time.

The occurrence position information of the fault output by the trained model varies depending on the fault factor. For example, the information regarding the section of the optical repeater in which the fault has occurred may be output targets in the case of a cable disconnection fault or an optical cable disconnection fault, but may not be output targets in the case of other faults. The information regarding the number of the optical repeater in which the fault has occurred is to be output in the case of failure of the optical repeater. Furthermore, the breaking point information of the cable is to be output in a case where the fault factor relates to breaking of the cable.

The output unit 24 outputs a fault factor in the entire submarine cable system from the trained model to which the input unit 23 has input the pre-processing log. That is, the trained model outputs the fault factor in the entire submarine cable system in a case where the input unit 23 inputs the pre-processing log. The output unit 24 can further output the occurrence probability of the fault factor. The occurrence probability of a fault factor is the probability of occurrence of the fault factor. The occurrence probability of a fault factor is typically expressed by a probability. That is, the output unit 24 can output the probability that a fault factor has occurred. For example, the output unit 24 can output a fault factor and an occurrence probability in association with each other, such as “fault factor: cable disconnection/occurrence probability: 85%”. The format output by the output unit 24 may be a table format or a matrix format. That is, as long as the fault factor and the occurrence probability are associated with each other, the output unit 24 can output them in any format.

The occurrence probability is not limited to the probability, and may be expressed in various formats. For example, the occurrence probability may be expressed by a category based on the occurrence probability. That is, “1” may be output in a case where the occurrence probability is 0% or more and less than 30%, “2” may be output in a case where the occurrence probability is 30% or more and less than 70%, “3” may be output in a case where the occurrence probability is 70% or more and 100% or less, and “3” may be output in a case where the occurrence probability is “85%”. In this case, the occurrence probability may be expressed by characters instead of numerical values, such as “high”, “medium”, and “low”. The output unit 24 may directly output such a representation by category from the trained model without being based on the occurrence probability.

The output unit 24 can output a plurality of fault factors. In other words, the output unit 24 can output a plurality of factors considered to be fault factors. That is, the output unit 24 can output all the fault factors having the occurrence probability. In this case, the output unit 24 outputs a plurality of occurrence probabilities relevant to the plurality of fault factors. Here, the output unit 24 may also output a fault factor having no occurrence probability. That is, the output unit 24 may also output a fault factor having an occurrence probability of 0%. For example, even in a case where a certain alarm/PM log is input to the trained model and the occurrence probability of optical fiber disconnection is 0%, the output unit 24 can output that there is no occurrence probability of optical fiber disconnection, such as “fault factor: optical fiber disconnection/occurrence probability: 0%”.

The output unit 24 may further output the occurrence position information of the fault based on the fault factor from the trained model. The output unit 24 transmits the fault factor and the occurrence probability thereof to the post- processing unit 25. In a case where the output unit 24 outputs the occurrence position information from the trained model, the output unit 24 transmits the occurrence position information to the post-processing unit 25.

The post-processing unit 25 receives the fault factor and the occurrence probability of the fault factor from the output unit 24. Then, based on the content, the post-processing unit 25 performs post-processing of generating a content to be displayed on the display unit 26. For example, in a case where the output unit 24 outputs one fault factor and one occurrence probability associated therewith, the post-processing unit 25 performs post-processing for displaying these factors on the display unit 26 in association with each other. For example, in a case where the output unit 24 outputs the contents of “fault factor: cable disconnection/occurrence probability: 85%” in a table format, the post-processing unit 25 causes the display unit 26 to display that the fault factor is “cable disconnection” and that the occurrence probability is “85%” so that the user can recognize them. Specifically, similarly to the output unit 24, the post-processing unit 25 can perform processing of displaying in a table format. The table may include information regarding an occurrence time of a fault.

In a case where the output unit 24 outputs a plurality of fault factors and a plurality of occurrence probabilities relevant to the fault factors, the post-processing unit 25 performs post-processing for displaying the plurality of fault factors and the occurrence probabilities output by the trained model on the graph in association with each other. That is, the post-processing unit 25 performs processing of visualizing a plurality of fault factors and occurrence probabilities with a graph. The graph may be any one of a pie chart, a histogram, a band graph, and a bar graph, or may be another graph.

In displaying the plurality of fault factors and the occurrence probabilities on the graph, the post-processing unit 25 can highlight and display a fault factor having a high occurrence probability. For example, in a case where the fault factor and the occurrence probability are visualized using a pie chart, the pie chart displays the area of the fault factor having a high occurrence probability in a large size. As a result, the post-processing unit 25 can highlight the fault factor having a high occurrence probability. Similarly, in a case where visualization is performed using a histogram, the histogram can display the area of the fault factor having a high occurrence probability in a large size. Even in a case where a band graph or a bar graph is used, in these graphs, the degree of occurrence probability can be displayed by the size of the area.

The post-processing unit 25 may add further processing to the generated graph to highlight the fault factor having a high occurrence probability. For example, in the case of using the pie chart, the post-processing unit 25 may highlight the fault factor by setting the hue, saturation, and brightness of the color of the portion indicating the fault factor having a high occurrence probability in the pie chart to a color tone that is emphasized relative to portions indicating other fault factors. In a case where the name of the fault factor is displayed on the graph, the post-processing unit 25 may highlight the fault factor having a high occurrence probability by changing the display color or the font size of the fault factor name.

The post-processing unit 25 can extract and calculate fault occurrence position information based on the fault factor received from the output unit 24. For example, in a case where the output unit 24 has not output the occurrence position information from the trained model, that is, in a case where the post-processing unit 25 has not received the occurrence position information from the output unit 24, the post-processing unit 25 generates the occurrence position information. In this case, the post-processing unit 25 generates, as the occurrence position information, information regarding the station building where the alarm has occurred, a section of the optical repeater where the fault has occurred, a number of the optical repeater where the fault has occurred, and breaking point information of the cable. In the case of generating the breaking point information of the cable, the post-processing unit 25 can generate the information based on, for example, a voltage value or a current value at the time of fault among the cable configuration information and the PM log related to power feeding.

The post-processing unit 25 performs post-processing for the occurrence position information to be displayed on the display unit 26 based on the occurrence position information of the fault. That is, the post-processing unit 25 performs post-processing for appropriately displaying information regarding the station building where the alarm has occurred, a section of the optical repeater where the fault has occurred, a number of the optical repeater where the fault has occurred, and information regarding a breaking point where the cable has broken.

Specifically, the post-processing unit 25 performs post-processing of the occurrence position information by referring to the pre-processing log at the occurrence time of the fault and extracting character string data from the alarm log relevant to the relevant pre-processing log. For example, in a case where the fault factor is estimated to be a repeater failure by the trained model, the post-processing unit 25 refers to the pre-processing log at the occurrence time of the fault to extract an alarm log by the optical repeater from the alarm log relevant to the pre-processing log. As a result, the post-processing unit 25 can generate information regarding the optical repeater in which the fault has occurred.

The post-processing unit 25 typically performs post-processing for displaying the occurrence position information in a table format. The post-processing unit 25 transmits the post-processed content to the display unit 26.

The display unit 26 is a display device including a liquid crystal panel, organic electroluminescence, or the like. The display unit 26 may be provided in a terminal owned by the user. Here, the terminal owned by the user is, for example, an information processing device such as a notebook personal computer (PC), a smartphone, or a tablet terminal.

The display unit 26 receives the post-processed content from the post-processing unit 25 and displays the content. That is, the display unit 26 displays the fault factor to the user. In a case where the occurrence probability for the fault factor is estimated by the trained model, the display unit 26 can display the fault factor and the occurrence probability thereof to the user. Furthermore, the display unit 26 can display a plurality of fault factors and occurrence probabilities on a graph in association with each other. In this case, the display unit 26 can highlight the fault factor having a high occurrence probability. Further, the display unit 26 can display fault occurrence position information based on fault factors.

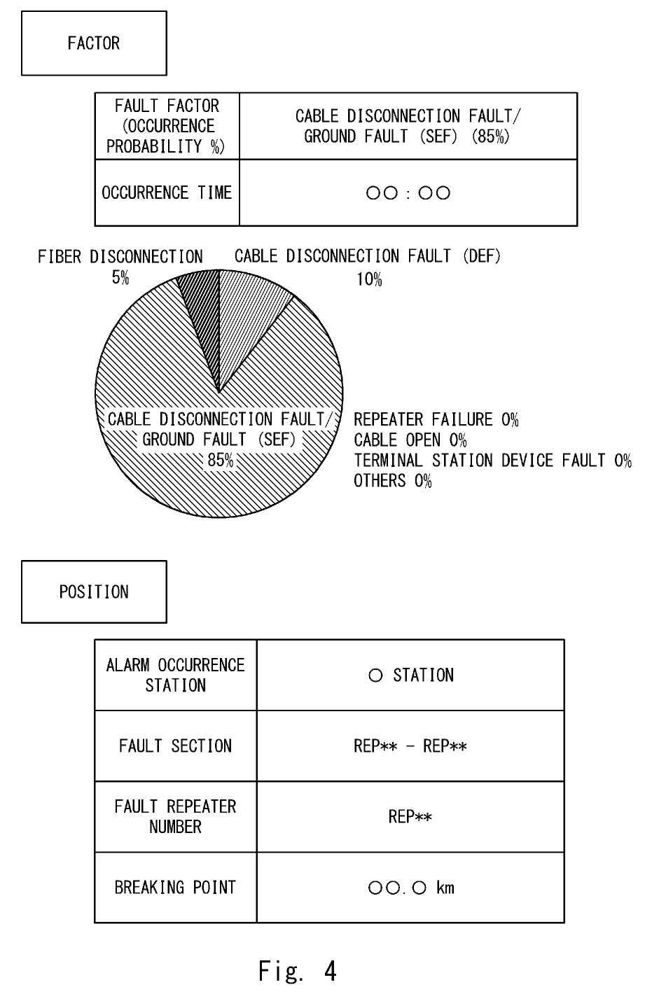

Here, an example of contents displayed by the display unit 26 will be described. FIG. 4 is a schematic diagram illustrating an example of contents displayed by the display unit 26. As illustrated in FIG. 4, the display unit 26 can indicate a fault factor in an upper stage and occurrence position information of a fault in a lower stage. In the fault factors in the upper stage, the fault factors, the occurrence probabilities, and the occurrence times of the faults are displayed in a table format. In the example of FIG. 4, “cable disconnection fault/ground fault (SEF)” is displayed as the fault factor. The occurrence probability of the fault factor is estimated to be “85%”. The occurrence probability is displayed together with the fault factor in the table.

A pie chart in which a plurality of fault factors and occurrence probabilities are associated with each other is displayed at a lower portion of the table displaying fault factors. In the example of FIG. 4, as the fault factor, “cable fault (DEF)” and “fiber disconnection” are estimated in addition to “cable disconnection fault/ground fault (SEF)”. The occurrence probabilities are “10%” and “5%”. Each fault factor and occurrence probability are displayed together in the pie chart. In the pie chart, a fault factor with an occurrence probability estimated to be “0%”, that is, a fault factor having no occurrence probability is also displayed. In FIG. 4, it is displayed that the occurrence probabilities of the fault factors of “repeater failure”, “cable open”, “terminal station device fault”, and “other” are “0%”.

In FIG. 4, fault occurrence position information is displayed in the lower part. The occurrence position information is also displayed in a table format similarly to the fault factor. In FIG. 4, information regarding “alarm occurrence station”, “fault section”, “fault repeater number”, and “breaking point” is displayed as the occurrence position information. As described above, some of these elements may not be displayed depending on the fault factor. For example, in FIG. 4, since the fault factor is estimated to be “cable disconnection fault/ground fault (SEF)”, the display unit 26 displays information regarding “alarm occurrence station”, “fault section”, and “breaking point” as the occurrence position information. On the other hand, the display unit 26 may not display information regarding the “fault repeater number”.

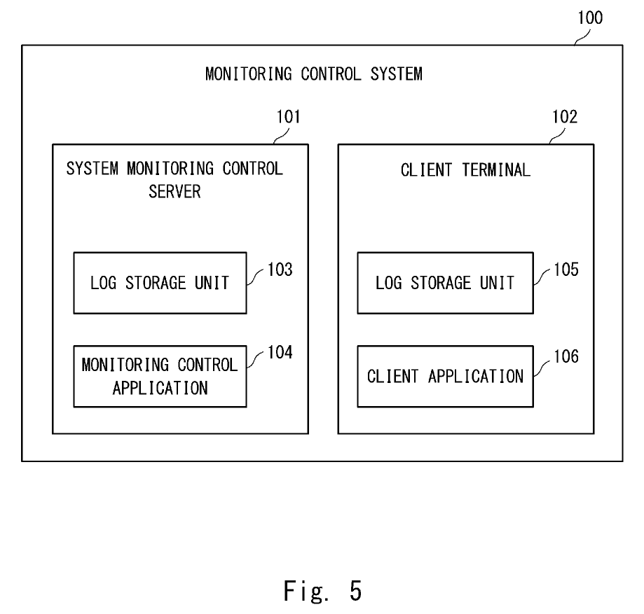

The fault determination system 2 according to the present example embodiment described above can be provided in a monitoring control system 100 in the submarine cable system. FIG. 5 is a block diagram illustrating a configuration of the monitoring control system 100. The monitoring control system 100 is a system that monitors an abnormality in the submarine cable system and collects logs from each configuration device in the submarine cable system to monitor and control each device.

The monitoring control system 100 includes a system monitoring control server 101 and a client terminal 102. The system monitoring control server 101 receives the alarm/PM log from the optical transmission terminal station device, the optical transmission device, the power feeding device, and the transmission path monitoring device provided in the station building. The system monitoring control server 101 may be provided for each station building, or one system monitoring control server 101 may collect logs from a plurality of station buildings. That is, one system monitoring control server 101 may monitor and control one station building or may monitor and control a plurality of station buildings. The monitoring control system 100 may include a plurality of system monitoring control servers 101. In particular, in a case where one system monitoring control server 101 monitors and controls one station building, the monitoring control system 100 includes a plurality of system monitoring control servers 101.

The client terminal 102 is a terminal mainly possessed by a user related to the submarine cable system. The client terminal 102 is data-communicably connected to the system monitoring control server 101, and the client terminal 102 can display the contents of the alarm/PM log to the user based on the information transmitted from the system monitoring control server 101. In the present second example embodiment, the client terminal 102 can display a fault factor in the submarine cable system and its occurrence probability to the user. The client terminal 102 is, for example, a notebook PC, a smartphone, or a tablet terminal. The monitoring control system 100 typically includes a plurality of client terminals 102, but the number of client terminals 102 may be one.

The system monitoring control server 101 includes a log storage unit 103 and a monitoring control application 104. The log storage unit 103 stores the alarm/PM log of each device in the submarine cable system received via the communication unit (not illustrated). The monitoring control application 104 is a program for implementing monitoring control of the station building targeted by the system monitoring control server 101. Based on the monitoring control application 104, a control unit (not illustrated) outputs an alarm/PM log to the client terminal 102. The client terminal 102 includes a log storage unit 105 and a client application 106. The log storage unit 105 stores the alarm/PM log received from the system monitoring control server 101. The client application 106 is a program for displaying predetermined information to the user who owns the client terminal 102.

The fault determination system 2 can be provided in the client terminal 102 in the monitoring control system 100. In other words, the function of the fault determination system 2 can be built in the client terminal 102. In this case, the fault determination system 2 inputs the alarm log or the alarm/PM log stored in the log storage unit 105 of the client terminal 102 to the trained model, and outputs the fault factor from the trained model. Then, the fault determination system 2 can cause the client terminal 102 to display the fault factor and the occurrence probability thereof. That is, the display unit 26 of the fault determination system 2 can be a display unit (not illustrated) of the client terminal 102.

Here, the fault determination system 2 may be provided in the system monitoring control server 101. That is, the fault determination system 2 may input the alarm log or the alarm/PM log stored in the log storage unit 103 of the system monitoring control server 101 to the trained model and output the fault factor from the trained model. The fault determination system 2 may cause the client terminal 102 to display the fault factor estimated in the system monitoring control server 101 and the occurrence probability thereof. That is, the function of the fault determination system 2 may be distributed to the system monitoring control server 101 and the client terminal 102.

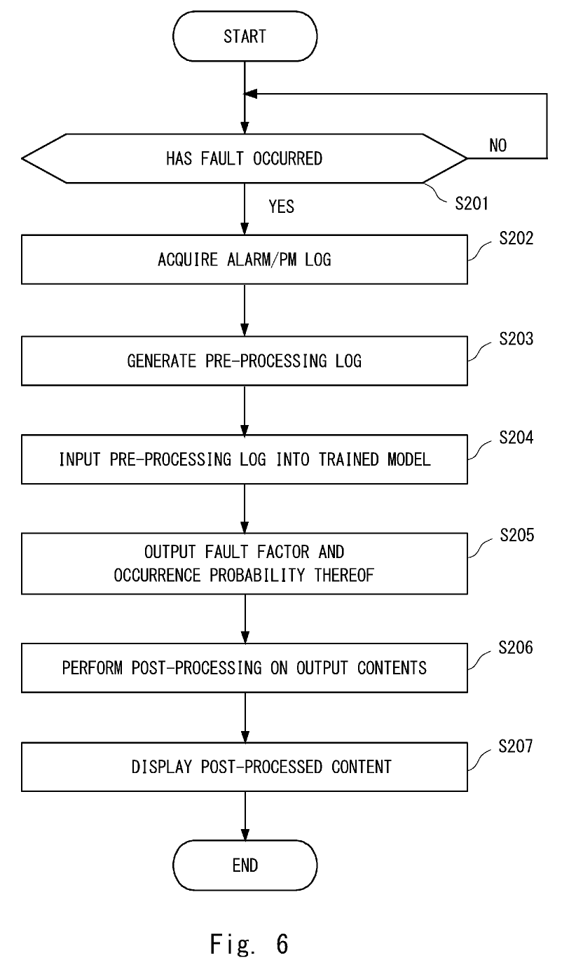

Next, a flow of a fault determination method by the fault determination system 2 will be described. FIG. 6 is a flowchart illustrating an example of a flow of a fault determination method by the fault determination system 2. First, the fault determination system 2 determines whether a fault occurs in the submarine cable system (S201). In a case where NO is determined in step S201, the process returns to step S201, and the fault determination system 2 performs the determination again. In a case where YES is determined in step S201, the acquisition unit 21 acquires alarm/PM logs output from a plurality of configuration devices in the submarine cable (S202). Next, the pre-processing unit 22 generates a pre-processing log by converting the character string indicating the log content related to the alarm/PM log acquired by the acquisition unit 21 into a numerical value (S203).

Thereafter, the input unit 23 inputs the pre-processing log generated by the pre-processing unit 22 to the trained model (S204). Thereafter, the output unit 24 outputs the plurality of fault factors and the occurrence probabilities thereof from the trained model (S205). Thereafter, the post-processing unit 25 performs post-processing for displaying the contents output by the output unit 24 on the display unit 26 (S206). Finally, the display unit 26 displays the display content generated by the post-processing unit 25 to the user (S207).

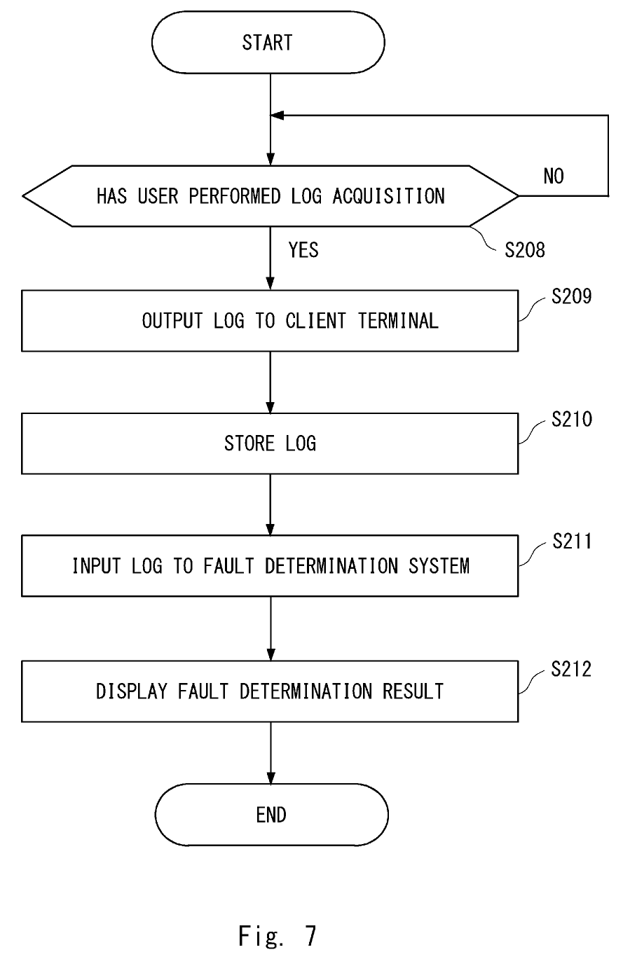

Next, a flow in a case where the fault determination system 2 is provided in the client terminal 102 in the monitoring control system 100 will be described. FIG. 7 is a flowchart illustrating an example of a flow of a fault determination method in the monitoring control system 100. First, the monitoring control system 100 determines whether the user has executed acquisition of the alarm/PM log (S208). In a case where NO is determined in step S208, the process returns to step S208, and the monitoring control system 100 performs the determination again. In a case where YES is determined in step S208, the system monitoring control server 101 outputs an alarm/PM log to the client terminal 102 (S209). In step S208, in a case where the system monitoring control server 101 detects the occurrence of the fault, the system monitoring control server 101 may automatically output the alarm/PM log to the client terminal 102. That is, the start of the operation in the monitoring control system 100 may be performed based on the intention of the user, or may be automatically performed by the monitoring control system 100.

Next, the client terminal 102 stores the received alarm/PM log in the log storage unit 105 (S210). Thereafter, the client terminal 102 inputs the alarm/PM log to the trained model (S211). Thereafter, the client terminal 102 displays the fault determination result to the user (S212). Here, the “fault determination result” refers to contents displayed by the display unit 26.

As described above, similarly to the fault determination system 1, the fault determination system 2 according to the present example embodiment can appropriately determine a fault factor in the entire submarine cable system. Specific effects of the fault determination system 2 are as follows. In the submarine cable system, in a case where a fault occurs, fault analysis and specification of a fault factor may be manually performed based on alarm logs and the like obtained from a plurality of configuration devices. However, specification of a fault factor in a submarine cable system requires a high degree of expertise. Fault analysis requires time and cost. Furthermore, such fault analysis work is likely to become individualized, and the work may depend on the knowledge level of the analyst.

The fault determination system 2 can output a fault factor of the submarine cable system by using the trained model based on the alarm log including the fault occurrence time. Therefore, the fault determination system 2 can automatically perform manual analysis work in a short time by machine learning. As a result, the fault determination system 2 can assist and speed up handling of a fault in the submarine cable system. According to the fault determination system 2, it is possible to perform fault determination even without expertise, and thus, it is possible to implement consistent fault handling without depending on a knowledge level.

The fault determination system 2 generates a pre-processing log by converting a character string indicating an alarm content related to the alarm log into a numerical value. Then, the fault determination system 2 inputs the pre-processing log to the trained model. At least a part of data stored as an alarm/PM log in the submarine cable system is a character string. However, in a case where it is desired to input the character string as it is to the trained model, it is necessary to use a model relevant to the input of the character string, but generation of such a training model may require a lot of time and cost. If an unpreprocessed alarm log is used as it is, the processing load of the system may increase. In the present example embodiment, the fault determination can be performed using a wide range of training models by converting the character string included in the log into a numerical value. This can reduce the processing load of the system. As a result, even in a case where the fault determination system 2 is introduced to a place (for example, an island) where communication is weak, it is possible to perform fault determination without significantly affecting original communication.

In the present example embodiment, the trained model further outputs the occurrence probability of the fault factor. As a result, the user, particularly the expert who performs the fault analysis, can finally specify the fault factor in consideration of the validity of the estimation by the trained model. For example, in a case where the occurrence probability output by the trained model is relatively low, the expert can consider the fault factor based on the fact that the trained model has not been able to estimate the fault factor with high probability.

The fault determination system 2 can display a plurality of fault factors and occurrence probabilities on a graph in association with each other. As a result, even a user who is not an expert but performs fault analysis can visually understand the factor of the fault that has occurred and the occurrence probability thereof. In particular, the fault determination system 2 can further support the understanding of the user by highlighting and displaying a fault factor having a high occurrence probability among the plurality of fault factors.

The fault determination system 2 can acquire the PM log together with the alarm log, whereby the fault determination system 2 can perform fault determination with high accuracy as compared with the case of using the alarm log. Then, the fault determination system 2 can generate a pre-processing log for the PM log by expressing an abnormal change in the variation amount of the monitored value in the acquired PM log with a numerical value. As a result, the fault determination system 2 can reduce the processing cost as compared with a case where the monitored value itself is input to the trained model.

The fault determination system 2 can further display the occurrence position information of the fault based on the fault factor output by the trained model. As a result, the user can grasp the estimated fault occurrence position information in a short time. As described above, in a case where the fault analysis is manually performed, it may take, for example, several days to determine the fault and specify the position. In this case, it is not possible to cope with the fault until these pieces of information are specified, and there is a possibility that the lead time until recovery is prolonged. According to the fault determination system 2, not only an expert but also a worker can grasp a fault factor and a fault occurrence position, so that it is possible to formulate a work plan for recovery and arrange a dedicated ship. Therefore, the lead time to recovery can be shortened. In particular, in a case where the fault factor relates to the breaking of the submarine cable, the user can understand the position of the breaking point in a short time by displaying the cable configuration information and the breaking point information calculated based on the PM log related to power feeding.

### Hardware Configuration Example

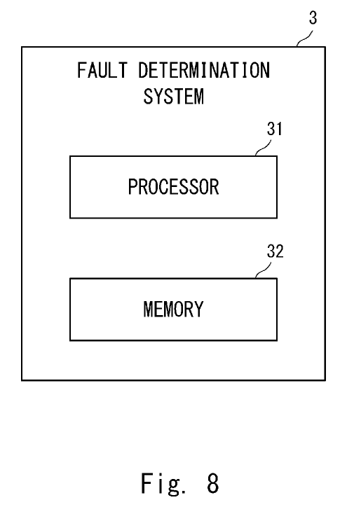

FIG. 8 is a diagram illustrating a hardware configuration example of a fault determination system 3. In FIG. 8, the fault determination system 3 includes a processor 31 and a memory 32. The processor 31 may be, for example, a microprocessor, a micro processing unit (MPU), or a central processing unit (CPU). The processor 31 may include a plurality of processors. The memory 32 is configured by a combination of a volatile memory and a nonvolatile memory. The memory 32 may include a storage located away from the processor 31. In this case, the processor 31 may access the memory 32 via an input/output (I/O) interface (not illustrated).

In the above-described example, a program can be stored and provided to a computer using any type of non-transitory computer readable media. Non-transitory computer readable media include any type of tangible storage media. Examples of non-transitory computer readable media include magnetic storage medium (for example, magneto-optical disk), CD-ROM (compact disc read only memory), CD-R (compact disc recordable), CD-R/W (compact disc rewritable), and semiconductor memory (for example, mask ROM, programmable ROM (PROM), erasable PROM (EPROM), flash ROM, and RAM). The program may be provided to a computer using any type of transitory computer readable media. Examples of transitory computer readable media include electrical signals, optical signals, and electromagnetic waves. Transitory computer readable media can provide the program to a computer via a wired communication line such as an electric wire and an optical fiber or a wireless communication line. The computer includes various information processing devices such as a PC, a server, a CPU, an MPU, a field programmable gate array (FPGA), and an application specific integrated circuit (ASIC).

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above-described example embodiments may also be described as the following Supplementary Notes, but are not limited to the following Supplementary Notes.

### Supplementary Note 1

A fault determination system including:

an acquisition unit that acquires an alarm log output from a plurality of configuration devices in a submarine cable system in which a fault has occurred, the alarm log including an occurrence time of the fault;

an input unit that inputs the alarm log acquired to a trained model that outputs a fault factor in the submarine cable system as a whole in a case where the alarm log is input; and

an output unit that outputs the fault factor relevant to the alarm log input from the trained model.

### Supplementary Note 2

The fault determination system according to Supplementary Note 1, further including a pre-processing unit that generates a pre-processing log by converting a character string indicating an alarm content related to the alarm log into a numerical value as pre-processing of the alarm log acquired by the acquisition unit,

wherein the input unit inputs the pre-processing log to the trained model as the alarm log.

### Supplementary Note 3

The fault determination system according to Supplementary Note 1 or 2, wherein the trained model further outputs an occurrence probability of the fault factor.

### Supplementary Note 4

The fault determination system according to Supplementary Note 3,

wherein the trained model outputs a plurality of the fault factor,

the fault determination system further including a display unit that displays the plurality of the fault factor and the occurrence probability output from the trained model in association with each other on a graph.

### Supplementary Note 5

The fault determination system according to Supplementary Note 4, wherein the display unit highlights the fault factor having a high occurrence probability among the plurality of the fault factor.

### Supplementary Note 6

The fault determination system according to any one of Supplementary Notes 2 to 5, wherein

the acquisition unit further acquires a performance monitoring (PM) log of the submarine cable system including the fault occurrence time, and

the pre-processing unit generates the pre-processing log by expressing an abnormal change in a variation amount of a monitored value in the PM log by a numerical value.

### Supplementary Note 7

The fault determination system according to any one of Supplementary Notes 4 to 6, wherein the display unit further displays occurrence position information of the fault based on the fault factor output by the trained model.

### Supplementary Note 8

The fault determination system according to Supplementary Note 7, wherein the occurrence position information includes breaking point information calculated based on cable configuration information in a case where the fault factor relates to breaking of a submarine cable.

### Supplementary Note 9

The fault determination system according to any one of Supplementary Notes 4 to 8, wherein the display unit displays the fault factor and the occurrence probability on a pie chart in association with each other.

### Supplementary Note 10

A fault determination method including,

by a computer:

acquiring an alarm log output from a plurality of configuration devices in a submarine cable system in which a fault has occurred, the alarm log including

an occurrence time of the fault;

inputting the alarm log acquired to a trained model that outputs a fault factor in the submarine cable system as a whole in a case where the alarm log is input; and

outputting the fault factor relevant to the alarm log input from the trained model.

### Supplementary Note 11

A program for causing a computer to execute:

a step of acquiring an alarm log output from a plurality of configuration devices in a submarine cable system in which a fault has occurred, the alarm log including an occurrence time of the fault;

a step of inputting the alarm log acquired to a trained model that outputs a fault factor in the submarine cable system as a whole in a case where the alarm log is input; and

a step of outputting the fault factor relevant to the alarm log input from the trained model.

### Supplementary Note 12

A trained model generation method including:

acquiring teacher data output from a plurality of configuration devices in a submarine cable system in which a fault has occurred, the teacher data including an alarm log including an occurrence time of the fault and a fault factor in the submarine cable system as a whole; and

generating a trained model that outputs the fault factor in a case where the alarm log is input, based on the teacher data.

### Supplementary Note 13

A trained model including a decision tree structure in which a branch condition is learned using teacher data in which an alarm log is an input, the alarm log being output from a plurality of configuration devices in a submarine cable system in which a fault has occurred, the alarm log including an occurrence time of the fault, and a fault factor in the submarine cable system as a whole is an output,

the trained model causing a computer to function to input the alarm log into the decision tree structure, and output the fault factor by branching.

Some or all of the elements (such as configurations and functions, for example) described in Supplementary Notes 2 to 9 dependent on Supplementary Note 1 may be dependent on Supplementary Notes 10 to 13 as well with dependent relationships similar to those of Supplementary Notes 2 to 9. Some or all of the elements described in any Supplementary Note may be applied to various types of hardware, software, recording means for recording software, systems, and methods.

1. A fault determination system comprising:
at least one memory storing instructions, and
at least one processor configured to execute the instructions to;
acquire an alarm log output from a plurality of configuration devices in a submarine cable system in which a fault has occurred, the alarm log including an occurrence time of the fault;
input the alarm log acquired to a trained model that outputs a fault factor in the submarine cable system as a whole in a case where the alarm log is input; and
output the fault factor relevant to the alarm log input from the trained model.

2. The fault determination system according to claim 1, wherein the at least one processor is further configured to execute the instructions to;
generate a pre-processing log by converting a character string indicating an alarm content related to the alarm log into a numerical value as pre-processing of the alarm log acquired, and
input the pre-processing log to the trained model as the alarm log.

3. The fault determination system according to claim 1, wherein the trained model further outputs an occurrence probability of the fault factor.

4. The fault determination system according to claim 3, wherein
the trained model outputs a plurality of the fault factor, and
the at least one processor is further configured to execute the instructions to display the plurality of the fault factor and the occurrence probability output from the trained model in association with each other on a graph.

5. The fault determination system according to claim 4, wherein the at least one processor is further configured to execute the instructions to highlight the fault factor having a high occurrence probability among the plurality of the fault factor.

6. The fault determination system according to claim 2, wherein the at least one processor is further configured to execute the instructions to;
acquire a performance monitoring (PM) log of the submarine cable system including the fault occurrence time, and
generate the pre-processing log by expressing an abnormal change in a variation amount of a monitored value in the PM log by a numerical value.

7. The fault determination system according to claim 4, wherein the at least one processor is further configured to execute the instructions to display occurrence position information of the fault based on the fault factor output by the trained model.

8. The fault determination system according to claim 7, wherein the occurrence position information includes breaking point information calculated based on cable configuration information in a case where the fault factor relates to breaking of a submarine cable.

9. The fault determination system according to claim 4, wherein the at least one processor is further configured to execute the instructions to display the fault factor and the occurrence probability on a pie chart in association with each other.

10. A fault determination method comprising,
by a computer:
acquiring an alarm log output from a plurality of configuration devices in a submarine cable system in which a fault has occurred, the alarm log including an occurrence time of the fault;
inputting the alarm log acquired to a trained model that outputs a fault factor in the submarine cable system as a whole in a case where the alarm log is input; and
outputting the fault factor relevant to the alarm log input from the trained model.

11. A trained model generation method comprising,
by a computer:
acquiring teacher data output from a plurality of configuration devices in a submarine cable system in which a fault has occurred, the teacher data including an alarm log including an occurrence time of the fault and a fault factor in the submarine cable system as a whole; and
generating a trained model that outputs the fault factor in a case where the alarm log is input, based on the teacher data.
